(19) United States
(12) Patent Application Publication
(10) Pub. No.: US 2012/0155001 A1
(43) Pub. Date: Jun. 21, 2012

(54) SECONDARY BATTERY AND PORTABLE ELECTRONIC DEVICE

(76) Inventors: Masato Fujikawa, Osaka (JP); Tomohiko Yokoyama, Osaka (JP); Keisuke Shimizu, Osaka (JP)

(21) Appl. No.: 13/393,781

(22) PCT Filed: May 10, 2010
(86) PCT No.: PCT/JP2010/003165

§ 371 Date: Mar. 1, 2012

(51) Int. Cl. H05K 7/00; H01M 2/08

(52) U.S. Cl. 361/679.01; 429/185

(57) ABSTRACT

A laminated film is used as a battery case to provide a secondary battery having high energy density and high strength. The secondary battery includes: a battery component 1; and an outer member for sealing the battery component 1, wherein the outer member includes a first layered sheet 2 having a first metal layer made of stainless steel and a first plastic layer, and a second layered sheet 3 having a second metal layer made of aluminum-based metal and a second plastic layer, the second layered sheet 3 is provided with a recess as a container part for containing the battery component 1, and the first plastic layer of the first layered sheet 2 and the second plastic layer of the second layered sheet 3 are thermally welded to seal the battery component 1.

### RELATED APPLICATIONS

This application is the U.S. National Phase under 35 U.S.C. §371 of International Application No. PCT/JP2010/003165, filed on May 10, 2010, which in turn claims the benefit of Japanese Application No. 2009-202644, filed on Sep. 2, 2009, the disclosures of which Applications are incorporated by reference herein.

### TECHNICAL FIELD

The present invention relates to secondary batteries and portable electronic devices, particularly to a secondary battery including a battery component and an outer member for sealing the battery component, and a portable electronic device using the secondary battery as a power source.

### BACKGROUND ART

Demand for secondary batteries as power sources of portable electronic devices has been increasing due to miniaturization and increasing variety of functions of the portable electronic devices, such as digital cameras, cellular phones, notebook computers, etc. In particular, lithium secondary batteries which are lightweight and have high energy density have practically been used as major power sources of the portable electronic devices, and technical development for achieving much higher energy density has actively been conducted.

In chemical batteries including the lithium secondary batteries, in general, a battery component obtained by stacking or winding a positive electrode plate and a negative electrode plate with a separator for electrically isolating the electrode plates and holding an electrolytic solution interposed between is sealed in a case. Two major methods for increasing the energy density of the secondary battery are a method of using active materials having higher capacity per volume in the electrode plates, and a method of reducing a volume of parts which do not contribute to a battery reaction.

To reduce the volume of the parts which do not contribute to the battery reaction, a technology of using a laminated film formed by bonding a metal sheet and a resin film as a battery case has been proposed and commercialized (see, e.g., Patent Document 1). The case made of the laminated film can greatly reduce the volume as compared with conventional cases made of a metal plate.

When the laminated film is used as the battery case, however, a tab for welding the laminated film is inevitably provided around the battery component. If the tab is too large, the battery becomes large, thereby reducing energy density of the battery. As a solution to this problem, a technology of embossing the laminated film to form a “dent” for placing the battery component therein has been proposed (see, e.g., Patent Document 2).

Regarding the laminated film used as the battery case, Patent Document 3 proposes a technology of using a high strength metal material, such as stainless steel etc., as the metal sheet in the laminated film.

Patent Document 4 proposes a technology of bonding two laminated films having metal layers of different thicknesses. One of the laminated films having the thicker metal layer is provided with a recess, and the battery component is placed in the recess.

### Citation List

### Patent Documents

[Patent Document 1] Japanese Patent Publication No. H03-62447

[Patent Document 2] Japanese Patent Publication No. H11-45688

[Patent Document 3] Japanese Patent Publication No. 2002-198016

[Patent Document 4] Japanese Patent Publication No. 2002-157981

### SUMMARY OF THE INVENTION

### Technical Problem

When the high strength stainless steel is used in the laminated film, the laminated film cannot be easily drawn to provide the recess for efficiently containing the battery component therein, particularly when the battery component is thick. However, if the stainless steel in the laminated film is thickened to perform deep drawing, the battery is thickened, thereby reducing the energy density.

In view of the foregoing, the present invention is concerned with using the laminated film as the battery case to provide the secondary battery with high energy density and high strength.

### Solution to the Problem

In view of the above concern, the secondary battery of the present invention includes: a battery component; and an outer member for sealing the battery component, wherein the outer member includes a first layered sheet having a first metal layer made of stainless steel and a first plastic layer, and a second layered sheet having a second metal layer made of aluminum-based metal and a second plastic layer, the second layered sheet is provided with a recess as a container part for containing the battery component, and the first plastic layer of the first layered sheet and the second plastic layer of the second layered sheet are thermally welded to seal the battery component.

The container part is preferably formed by drawing.

The first layered sheet preferably has a third plastic layer covering the first metal layer, and the second layered sheet preferably has a fourth plastic layer covering the second metal layer.

A first portable electronic device according to the present invention includes the secondary battery, and the secondary battery is arranged in such a manner that a surface of the secondary battery covered with the second layered sheet faces a substrate of the portable electronic device.

A second portable electronic device according to the present invention includes the secondary battery, and a surface of the secondary battery covered with the first layered sheet is exposed or covered with a cover.

### ADVANTAGES OF THE INVENTION

According to the present invention, the two layered sheets having different strengths are used, and the lower strength second layered sheet is provided with the recess to seal the battery component. This can reduce the volume of the outer member in the total volume of the second battery, and can increase the energy density.

### BRIEF DESCRIPTION OF THE DRAWINGS

FIG. 1 is a cross-sectional view schematically illustrating a lithium secondary battery according to an embodiment of the present invention.

FIG. 2 is a cross-sectional view schematically illustrating a laminated film according to the embodiment of the present invention.

FIG. 3 is a cross-sectional view schematically illustrating a portable electronic device using the lithium secondary battery according to the embodiment of the present invention as a power source.

### DESCRIPTION OF EMBODIMENTS

The aluminum-based metal includes an alloy at least 95% of which is aluminum, and composite metal made of aluminum on a surface of which a metal material except for aluminum having a thickness of 1/10 or smaller of the aluminum is stacked. The substrate of the portable electronic device is a circuit board on which electronic parts as the components of the portable electronic device are mounted.

Embodiments of the present invention will be described with reference to the drawings. The same components will be indicated by the same reference characters. The present invention is not limited to the following description as long as the invention is based on the fundamental features described in the specification.

### First Embodiment

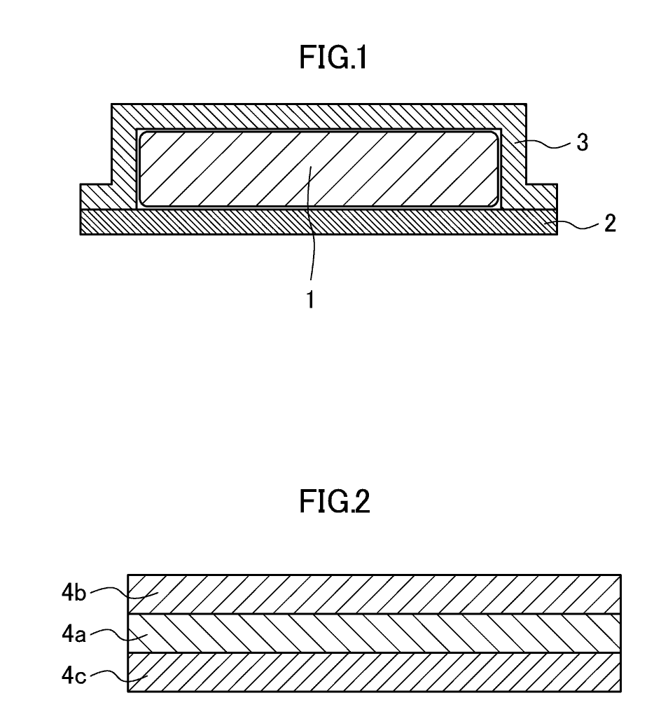

FIG. 1 is a cross-sectional view schematically illustrating a lithium secondary battery according to a first embodiment. In FIG. 1, details are not shown in the cross-sectional view for easy understanding. The lithium secondary battery of the present embodiment (hereinafter may be referred to as a “battery”) includes a battery component 1 including a positive electrode plate and a negative electrode plate facing the positive electrode plate which are wound or stacked with a porous insulator interposed therebetween. The battery component 1 and an electrolyte having lithium ion conductivity (not shown) are contained in a case formed with an outer member including layered sheets. The outer member includes a first layered sheet 2 having a first metal layer and a first plastic layer, and a second layered sheet 3 having a second metal layer which is lower in strength than the first metal layer and a second plastic layer. The second layered sheet 3 is pressed or drawn to form a recess as a container part for containing the battery component 1. The first and second layered sheets 2 and 3 are bonded together by thermally welding the plastic layers.

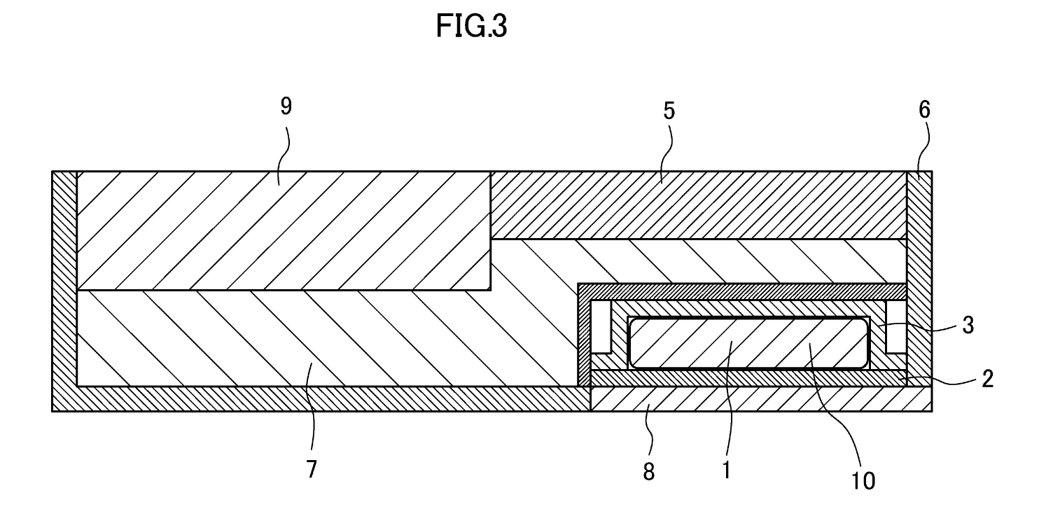

FIG. 2 is a cross-sectional view of the layered sheet of the present embodiment. The first and second layered sheets 2 and 3 have the same structure, and the following description will be applied to the both. In the present embodiment, the layered sheet includes a metal layer 4a as a base, a plastic layer as an adhesive layer 4b (corresponding to the first plastic layer of the first layered sheet and the second plastic layer of the second layered sheet), and a protective layer 4c (corresponding to a third plastic layer of the first layered sheet and a fourth plastic layer of the second layered sheet). The adhesive layer 4b is stacked on one side of the metal layer 4a, and the protective layer 4c is stacked on the other side of the metal layer 4a. The layered sheet may include at least two layers, i.e., the metal layer 4a and the adhesive layer 4b, and the protective layer 4c is not essential.

The metal layer 4a ensures mechanical strength of the layered sheet. The first and second metal layers have different strengths. The strength of the metal layer 4a can be varied by changing the material or the thickness of the metal layer, or thermally treating the metal layer. The strength is represented by product YT of Young's modulus Y and thickness T of the metal layer. The product YT of the higher strength metal layer is preferably 5 (kgf/μm) to 20 (kgf/μm), both inclusive. The product YT of the lower strength metal layer is preferably 2 (kgf/μm) to 4 (kgf/μm), both inclusive. The lower strength metal layer is preferably made of aluminum, an aluminum alloy, a magnesium alloy, titanium, etc. The higher strength metal layer is preferably made of stainless steel (austenitic stainless steel, martensitic stainless steel, ferritic stainless steel), nickel, iron, etc.

The adhesive layer 4b is provided to thermally weld the layered sheets, and the protective layer 4c is provided to improve flexibility, an insulating property, or an anti-corrosion property of the metal layer 4a. The metal layer 4a is thermally welded, or adhered with an adhesive, to the adhesive layer 4b and the protective layer 4c. The layered sheets are generally bonded by stacking the two layered sheets with their adhesive layers 4b facing each other, and press-welding the sheets while applying heat thereto. The adhesive layer 4b is preferably made of a resin such as polypropylene, polyethylene, etc. The protective layer 4c is preferably made of a resin having a higher melting point than the resin constituting the adhesive layer 4b, e.g., nylon 6, nylon 610, nylon 66, polyamide, polyimide, etc., so that the protective layer is not molten in bonding the layered sheets.

The adhesive layer 4b preferably has a thickness of about 20 μm to 100 μm. When the thickness is less than 20 μm, the layered sheets are not bonded well, and capability of sealing the battery becomes poor. This may cause leakage of an electrolytic solution, or penetration of moisture in the battery component 1. When the thickness exceeds 100 μm, the outer member becomes thick, and the energy density of the battery is reduced.

In the structure shown in FIG. 1, the first layered sheet 2 ensures the strength of the battery, and the volume of the battery can be reduced by drawing the second layered sheet 3 which is easy to process. This can increase the energy density of the battery, and can provide the battery with resistance to shock.

The metal layers of the first layered sheet 2 and the second layered sheet 3 are preferably made of different metal materials to make the strengths of the first and second layered sheets different. When the metal layers are thickened to increase the strength, the battery becomes thick, thereby causing unwanted reduction of the energy density.

The second metal layer of the second layered sheet 3 is preferably made of aluminum-based metal. Aluminum is flexible and extensible. Thus, the container part can easily be formed by processing, and a battery having a large volume can be contained. In addition, use of aluminum can increase the energy density per weight of the battery because aluminum has low density and is lightweight.

The first metal layer of the first layered sheet 2 is preferably made of stainless steel. Stainless steel is highly rigid, and can provide high strength even when it is thin. Thus, use of stainless steel can prevent break of the battery component inside the case even when the battery is shocked or dropped, thereby ensuring high safety.

The present embodiment is particularly advantageous when applied to a high output lithium secondary battery having high energy density.

The container part for containing the battery component is formed in the second layered sheet by pressing (particularly drawing) the second layered sheet. Thus, the second layered sheet can be processed in a short time. In addition, thermal damage to the second layered sheet can be reduced, thereby providing the product with high strength. The drawing can more stably process the sheet into the same shape than the other pressing techniques, such as bulging etc.

Parts constituting the battery component will be described below. In the present embodiment, materials and structures of the positive electrode plate, the negative electrode plate, the separator, and the electrolyte are not limited to the following examples.

The positive electrode plate includes a positive electrode current collector, and a positive electrode active material layer. The positive electrode active material layer contains a positive electrode active material as an essential ingredient, and optionally contains a conductive agent, a binder, etc. The positive electrode active material may preferably contain lithium-containing composite oxide represented by, e.g., a general formula: LiₓM₁₋ₓO₂ (M=Co, Ni, Mn, etc.). Examples of the lithium-containing composite oxide may include LiCoO₂, LiNiO₂, Li₂MnO₄, etc. The positive electrode active material may further contain olivine-type lithium phosphate represented by a general formula: LiMPO₄ (M is at least one element selected from the group consisting of V, Fe, Ni, and Mn), lithium fluorophosphate represented by a general formula: Li₂MPO₄F (M is at least one element selected from the group consisting of V, Fe, Ni, and Mn), etc. Elements constituting the lithium-containing compounds may partially be substituted with other elements. The positive electrode active material may be surface-treated with metal oxide, lithium oxide, a conductive agent, etc., or a surface thereof may be hydrophobized.

Examples of the conductive agent may include graphites such as natural graphites and artificial graphites, carbon blacks such as acetylene black, Ketchen black, channel black, furnace black, lamp black, thermal black, etc., conductive fibers such as carbon fibers, metal fibers, etc., carbon fluoride, metal powders such as aluminum etc., conductive whiskers such as zinc oxide, potassium titanate, etc., conductive metal oxides such as titanium oxide, organic conductive materials such as phenylene derivatives, etc. The conductive agents may be used alone or in combination of two or more of them.

Examples of the binder may include polyvinylidene fluoride (PVDF), polytetrafluoroethylene, polyethylene, polypropylene, aramid resin, polyamide, polyimide, polyamide imide, polyacrylonitrile, polyacrylic acid, poly(methyl acrylate), poly(ethyl acrylate), poly(hexyl acrylate), polymethacrylic acid, poly(methyl methacrylate), poly(ethyl methacrylate), poly(hexyl methacrylate), poly(vinyl acetate), polyvinylpyrrolidone, polyether, polyether sulfone, hexafluoropolypropylene, styrene-butadiene rubber, carboxymethyl cellulose, etc. A copolymer containing two or more substances selected from the group consisting of tetrafluoroethylene, hexafluoropropylene, perfluoroalkyl vinyl ether, vinylidene fluoride, chlorotrifluoroethylene, ethylene, propylene, pentafluoropropylene, fluoromethyl vinyl ether, acrylic acid, and hexadiene may be used. The binders may be used alone or in combination of two or more of them.

The positive electrode current collector is not particularly limited. For example, the positive electrode current collector may be made of aluminum (Al), carbon, a conductive resin, etc. The positive electrode current collector may be surface-treated with carbon.

The negative electrode plate includes a negative electrode current collector, and a negative electrode active material layer. The negative electrode active material layer contains a negative electrode active material as an essential ingredient, and optionally contains a binder etc. Examples of the negative electrode active material may include carbon materials (e.g., various types of natural graphites and artificial graphites), materials containing Si (Si alone, Si alloys, SiOₓ (0<x<2), etc.), materials containing Sn (Sn alone, Sn alloys, SnO, etc.), lithium metals, etc. The lithium metals include lithium alone, and lithium alloys containing Al, Zn, Mg, etc. The negative electrode active materials may be used alone or in combination of two or more of them.

The binder for the negative electrode plate is not particularly limited. For example, the same binders as those listed above in connection with the positive electrode plate may be used.

The negative electrode current collector is not particularly limited. For example, the negative electrode current collector may be metal foil made of stainless steel, nickel, copper, titanium, etc., or a thin film made of carbon or a conductive resin. The negative electrode current collector may be surface-treated with carbon, nickel, titanium, etc.

Examples of the nonaqueous electrolyte may include a liquid nonaqueous electrolyte containing a nonaqueous solvent and a solute dissolved in the nonaqueous solvent, a polymer electrolyte containing a liquid nonaqueous electrolyte and a high molecular compound, etc.

The solute is not particularly limited. For example, the solute may suitably be selected in view of oxidation-reduction potential etc. Preferable examples of the solute may include LiPF₆, LiBF₄, LiClO₄, LiAlCl₄, LiSbF₆, LiSCN, LiCF₃SO₃, LiNCF₃CO₂, LiAsF₆, LiB₁₀Cl₁₀, lower aliphatic lithium carboxylate, LiF, LiCl, LiBr, LiI, chloroborane lithium, borates such as lithium bis(1,2-benzenediolate(2-)-O,O′)borate, lithium bis(2,3-naphthalenediolate(2-)-O,O′)borate, lithium bis(2,2′-biphenyldiolate(2-)-O,O′)borate, and lithium bis(5-fluoro-2-olate-1-benzensulfonate-O,O′)borate, LiN(CF₃SO₂)₂, LiN(CF₃SO₂)(C₄F₉SO₂), LiN(C₂F₅SO₂)₂, lithium tetraphenylborate, etc. The solutes may be used alone or in combination of two or more of them.

The nonaqueous solvent is not particularly limited. Examples of the nonaqueous solvent may include ethylene carbonate (EC), propylene carbonate, butylene carbonate, vinylene carbonate, dimethyl carbonate (DMC), diethyl carbonate, ethyl methyl carbonate (EMC), dipropyl carbonate, methyl formate, methyl acetate, methyl propionate, ethyl propionate, dimethoxymethane, γ-butyrolactone, γ-valerolactone, 1,2-diethoxyethane, 1,2-dimethoxyethane, ethoxy methoxy ethane, trimethoxy methane, tetrahydrofuran, tetrahydrofuran derivatives such as 2-methyltetrahydrofuran etc., dimethyl sulfoxide, 1,3-dioxolane, dioxolane derivatives such as 4-methyl-1,3-dioxolane etc., formamide, acetamide, dimethylformamide, acetonitrile, propylnitrile, nitromethane, ethyl monoglyme, trialkyl phosphate, acetate, propionate, sulfolane, 3-methylsulfolane, 1,3-dimethyl-2-imidazolidinone, 3-methyl-2-oxazolidinone, propylene carbonate derivatives, ethyl ether, diethyl ether, 1,3-propane sultone, anisole, fluorobenzene, etc. The nonaqueous solvents may be used alone or in combination of two or more of them.

The nonaqueous electrolyte may contain an additive. The additive is not particularly limited. Examples of the additive may include vinylene carbonate, cyclohexylbenzene, biphenyl, diphenyl ether, vinyl ethylene carbonate, divinyl ethylene carbonate, phenyl ethylene carbonate, diallyl carbonate, fluoroethylene carbonate, catechol carbonate, vinyl acetate, ethylene sulfite, propanesultone, trifluoropropylene carbonate, dibenzofuran, 2,4-difluoroanisole, o-terphenyl, m-terphenyl, etc. The additives may be used alone or in combination of two or more of them.

The nonaqueous electrolyte may be a solid electrolyte containing a high polymer material, or a gelled electrolyte containing a nonaqueous solvent. Examples of the high polymer material may include polyethylene oxide, polypropylene oxide, polyphosphazene, polyaziridine, polyethylene sulfide, polyvinyl alcohol, polyvinylidene fluoride, polyhexafluoropropylene, etc.

When the gelled nonaqueous electrolyte is used, the gelled nonaqueous electrolyte may be arranged in place of the separator between the positive and negative electrode plates. Alternatively, the gelled nonaqueous electrolyte may be arranged adjacent to the separator.

As the solid electrolyte, inorganic materials such as lithium nitride, lithium halide, lithium oxoate, Li₄SiO₄, Li₄SiO₄—LiI—LiOH, Li₃PO₄—Li₄SiO₄, Li₂SiS₃, Li₃PO₄—Li₂S—SiS₂, phosphorus sulfide compounds, etc. may be used.

Examples of the separator may include nonwoven fabric or a microporous film containing at least one substance selected from the group consisting of polyethylene, polypropylene, aramid resin, amide imide, polyphenylene sulfide, and polyimide. When the liquid nonaqueous electrolyte is used, the separator is impregnated with the liquid nonaqueous electrolyte.

A heat-resistant filler such as alumina, magnesia, silica, titania, etc., may be contained in the separator or a surface of the separator.

In addition to the separator, a heat-resistant layer containing the heat-resistant filler, and a binder similar to the binder contained in the positive and negative electrode plates may be formed. The heat-resistant layer may be formed on a surface of any of the positive electrode plate, the negative electrode plate and the separator.

The present embodiment provides the most significant advantages when applied to high output lithium secondary batteries having high energy density. However, the secondary batteries to which the present embodiment is applicable are not limited to the lithium ion secondary batteries. For example, similar advantages can be obtained when the present embodiment is applied to, e.g., alkaline secondary batteries, lead-acid batteries, etc.

### Portable Electronic Device

FIG. 3 is a cross-sectional view illustrating a portable electronic device using the secondary battery of the present embodiment as a power source.

In the portable electronic device using the secondary battery of the present embodiment as the power source, a surface of the secondary battery consisted of the lower strength second layered sheet is more protected from external impact by a component of the portable electronic device than a surface consisted of the first layered sheet. Specifically, the surface consisted of the lower strength second layered sheet is protected by arranging the secondary battery in the portable electronic device with the second layered sheet facing a substrate of the portable electronic device.

In a general portable electronic device using the secondary battery as a power source, a casing 6 contains an operating part 5, an electronic circuit (including the substrate) 7, a display part 9, etc. A secondary battery 10 is generally placed in an outer part of the electronic device, and is covered with a battery cover 8. The battery cover 8 is made thinner with reduction in thickness of the portable electronic device, and some battery covers can also function as an outer member of the battery. Thus, when the portable electronic device receives impact, the secondary battery 10 experiences considerable impact. However, as shown in FIG. 3, the secondary battery 10 is arranged in such a manner that the surface of the secondary battery 10 consisted of the higher strength first layered sheet 2 faces outside the portable electronic device, and the surface consisted of the second layered sheet 3 faces inside the portable electronic device to be protected by the substrate of the electronic circuit 7. Thus, the first layered sheet 2 receives the impact externally applied to the portable electronic device. This can reduce influence on the battery component 1.

### Other Embodiments

The above-described embodiment has been described merely as an example of the present invention, and the present invention is not limited to the embodiment.

In the portable electronic device using the secondary battery as a power source, the surface of the secondary battery consisted of the lower strength second layered sheet is more protected from the external impact by the component of the portable electronic device than the surface consisted of the first layered sheet. To achieve such a structure, the surface consisted of the higher strength first layered sheet may be exposed, or may be protected merely by the case of the portable electronic device, while the surface consisted of the second layered sheet may be protected by both of the case and the component in the device. Alternatively, the secondary battery may be arranged in such a manner that a distance between the surface consisted of the first layered sheet and the case of the portable electronic device facing the surface is smaller than a distance between the surface consisted of the second layered sheet and the case of the portable electronic device facing the surface.

### INDUSTRIAL APPLICABILITY

As described above, the secondary battery of the present invention has high energy density and high strength, and is useful for power sources of, e.g., mobile data terminals, portable electronic devices, low power storage units for home use, motorcycles, electric cars, hybrid electric cars, etc.

### DESCRIPTION OF REFERENCE CHARACTERS

1 Battery component

2 First layered sheet

3 Second layered sheet

4a Metal layer

4b Adhesive layer

4c Protective layer

5 Operating part

6 Casing

7 Electronic circuit

8 Battery cover

9 Display part

10 Secondary battery

1. A secondary battery comprising:
a battery component; and
an outer member for sealing the battery component, wherein
the outer member includes a first layered sheet having a first metal layer made of stainless steel and a first plastic layer, and a second layered sheet having a second metal layer made of aluminum-based metal and a second plastic layer,
a product of a Young's modulus and a thickness of the first metal layer is 5 (kgf/μm) to 20 (kgf/μm), both inclusive, and a product of a Young's modulus and a thickness of the second metal layer is 2 (kgf/μm) to 4 (kgf/μm), both inclusive,
the second layered sheet is provided with a recess as a container part for containing the battery component, and
the first plastic layer of the first layered sheet and the second plastic layer of the second layered sheet are thermally welded to seal the battery component.

2. The secondary battery of claim 1, wherein
the container part is formed by drawing.

3. The secondary battery of claim 1, wherein
the first layered sheet has a third plastic layer covering the first metal layer, and
the second layered sheet has a fourth plastic layer covering the second metal layer.

4. A portable electronic device in which the secondary battery of claim 1 is mounted, wherein
the secondary battery is arranged in such a manner that a surface of the secondary battery covered with the second layered sheet faces a substrate of the portable electronic device.

5. A portable electronic device in which the secondary battery of claim 1 is mounted, wherein
a surface of the secondary battery covered with the first layered sheet is exposed or covered with a cover.
